(19) United States
(12) Patent Application Publication
(10) Pub. No.: US 2025/0040046 A1
(43) Pub. Date: Jan. 30, 2025

(54) A PRINTED CIRCUIT BOARD ARRANGEMENT AND WAVEGUIDE INTERFACE ARRANGEMENT

(71) Applicant: Telefonaktiebolaget LM Ericsson (publ), Stockholm (SE)

(72) Inventor: Klas ERIKSSON, Kungsbacka (SE)

(21) Appl. No.: 18/716,359

(22) PCT Filed: Dec. 6, 2021
(86) PCT No.: PCT/SE2021/051209

§ 371 Date: Jun. 4, 2024

(51) Int. Cl. H05K 1/11; H05K 1/02; H05K 3/40

(52) U.S. Cl. CPC H05K 1/115; H05K 1/0237; H05K 3/4038

(57) ABSTRACT

The present disclosure relates to a PCB arrangement for electrically connecting a microwave conductor to a waveguide device. The PCB arrangement includes at least one PCB dielectric layer a first PCB main side with a first PCB metallization where the microwave conductor is formed, a second PCB main side with a second PCB metallization having an aperture. The second PCB main side is adapted for attachment of a waveguide device via the aperture. The PCB arrangement further includes a via connection running between, and electrically connecting, a microwave conductor end portion and a radiating element in the aperture, and a first electric connection arrangement running between, and electrically connecting, the second PCB metallization and an adjacent PCB metallization included in the PCB arrangement.

### TECHNICAL FIELD

The present disclosure relates to wireless communication systems, and in particular to a printed circuit board arrangement and a waveguide interface arrangement adapted for electrically connecting a waveguide interface to a microwave conductor.

### BACKGROUND

In many fields of wireless communication, such as microwave communication, as well as for applications associated with radars and other sensors using microwave technology, waveguides are used for transporting wireless signals, due to the low losses incurred in a waveguide.

In many applications, microwave radios are using waveguides as interface to antennas and/or diplexer filters. Therefore, it is common to use a microstrip to waveguide transition in the design since integrated circuits (ICs) and printed circuit boards (PCBs) use planar transmission lines.

This transition is normally designed around a PCB where there is a waveguide port one side of the PCB and a shorted waveguide, a so called backshort, on the other side. The waveguide port continues to the next radio frequency (RF) component in waveguide technology, for example a diplexer filter, and the backshort continues a relatively short distance, e.g. a quarter wavelength, before it is short circuited, and is used for reflecting the wave back through the waveguide port. The port comprises a radiating element, a probe, inserted inside the waveguide port connected to a planar transmission line

Traditionally a backshort is a mechanical part, made in metal, which is pushed against the PCB with springs, screws or similar devices. There could also be electrical gaskets in the interfaces to minimize potential leakages. For some applications conductive glue and soldering can be used.

There are certain obstacles with the existing solutions, for example leakage, cost and thermal mismatch. Furthermore, at higher frequencies, for example beyond 130 GHz, the design of a waveguide transition becomes increasingly difficult. The main reason for this is that it is difficult to scale mechanical dimensions and manufacturing tolerances in the same order as the wavelength, where transitions and thereby the packaging of the RF circuits depend on high precision mechanical machining, expensive processing, and exotic and high cost materials.

An example of an existing solution is shown in a cut-open side view in FIG. 1, where a module P100 comprises a PCB P101 with an IC P102 positioned on a top side P108, where the IC P102 is connected to a microstrip conductor P103 via a bond wire P104. The microstrip conductor P103 ends in a probe P105. A vertical waveguide part P106 is positioned such that it faces a bottom side P109 of the PCB P101 and an opposing metal backshort P107 is placed on the top side P108, covering the probe P105.

The existing planar waveguide transitions used at lower frequencies are difficult to scale to higher frequencies with maintained low cost and sufficient performance. The common building practice consists of several parts that all must be manufactured and assembled with high precision with several junctions that must be aligned and have a good electrical connection, where such junctions may suffer from misalignment. With the dimensions shrunk to adopt to higher frequencies, such misalignments will result in unacceptable RF performance.

Existing transitions designed for higher frequencies, for example beyond 130 GHz, are all too expensive to be used in future point-to-point radios, either due to required high precision machining, complex assembly, high cost materials, or expensive processing. Transitions based on SIW topology requires high cost materials or complex processing to keep the losses low at the frequencies of interest. It also follows from the above that existing solutions at lower frequencies also suffer from problems.

In order to develop future point-to-point radios operating at relatively high frequencies, for example beyond 130 GHz but also at lower frequencies, it is essential to find a low-cost planar-TML-to-WG transition that maintain acceptable RF performance, i.e. insertion loss and return loss, over the frequency bands of interest.

There is thus a need for an improved waveguide transition arrangement adapted for electrically connecting a waveguide interface to a microwave conductor, where the above drawbacks are minimized, for example providing an at least sufficient RF performance regarding insertion loss and return loss, over the frequency bands of interest.

### SUMMARY

It is an object of the present disclosure to provide an improved waveguide transition arrangement adapted for electrically connecting a waveguide interface to a microwave conductor where the above drawbacks are minimized.

Said object is obtained by means of a printed circuit board (PCB) arrangement arranged for electrically connecting a microwave conductor to a waveguide device. The PCB arrangement comprises at least one PCB dielectric layer and a first PCB main side with a first PCB metallization, where the microwave conductor is formed in the first PCB metallization. The PCB arrangement further comprises a second PCB main side with a second PCB metallization, and an aperture in the second PCB metallization. The second PCB main side is adapted for attachment of a waveguide device via the aperture that is adapted to correspond to a waveguide aperture. The PCB arrangement further comprises a via connection running between, and electrically connecting, a microwave conductor end portion and a radiating element arranged in the aperture, and a first electric connection arrangement running between, and electrically connecting, the second PCB metallization and an adjacent PCB metallization comprised in the PCB arrangement. The first electric connection arrangement is arranged to circumvent the aperture such that a waveguide backshort is formed in the PCB arrangement, the waveguide backshort being limited by the first connection arrangement and the adjacent PCB metallization.

This means that a waveguide backshort is obtained within the PCB arrangement, no separate part being needed or having to be mounted in order to obtain a waveguide backshort. For example, front-end circuitry and ICs can be positioned on the first PCB main side, and a waveguide device can be positioned on the second PCB main side. This enables integration of an entire planar transmission line to waveguide transition in a PCB,

According to some aspects, the adjacent PCB metallization is the first PCB metallization. This means that the PCB arrangement only comprising one dielectric layer where a waveguide backshort is formed in the dielectric layer by means of an electric connection arrangement running between, and electrically connecting, the second PCB metallization and the adjacent PCB metallization that is the same as the first PCB metallization. In this manner, a compact PCB arrangement that provides a waveguide transition is obtained.

According to some aspects, the adjacent PCB metallization is an intermediate PCB metallization. This means that the PCB arrangement can be applied for two or more dielectric layers, resulting in a large range of possibilities.

According to some aspects, the via connection is circumvented by a second electric connection arrangement running between, and electrically connecting, the first PCB metallization and the adjacent PCB metallization. In this way, microwave radiation is prevented from leaking in the first dielectric layer, and possible resonances are attenuated.

According to some aspects, at least one electric connection arrangement comprises a plurality of vias. This means that the electric connection arrangement can be accomplished by using well-known technology and manufacturing processes.

According to some aspects, the microwave conductor end portion comprises a matching portion. This can provide desired electrical properties regarding for example transmission and reflection for signal that are being transferred between a mounted waveguide device and the microwave conductor end portion.

According to some aspects, the microwave conductor is a coplanar waveguide conductor that is surrounded by at least a part of the rest of the first PCB metallization. This provides a compact and reliable design.

According to some aspects, the PCB arrangement is adapted to be mounted to a waveguide device that at least initially has a main extension that runs perpendicular to a main extension of the second PCB main side. Alternatively, or additionally, the PCB arrangement is adapted to be mounted to a waveguide device that at least initially has a main extension that runs parallel to a main extension of the second PCB main side. This means that the PCB arrangement is suitable for different types of a waveguide devices, such as surface-mounted waveguide devices.

This object is also obtained by means of waveguide interface arrangements and methods that are associated with the above advantages.

### BRIEF DESCRIPTION OF THE DRAWINGS

The present disclosure will now be described more in detail with reference to the appended drawings, where:

FIG. 1 shows a schematic cut-open side view of a prior art waveguide interface arrangement;

FIG. 2 shows a schematic exploded perspective view of a first example of a a PCB arrangement together with a waveguide device;

FIG. 3 shows a schematic cut-open side view of the first example of the PCB arrangement 106 together with a waveguide device;

FIG. 4 shows a schematic top view of the first example of the PCB arrangement 106;

FIG. 5 corresponds to FIG. 4 with one dielectric layer removed;

FIG. 6 shows a schematic side view of the first example of the PCB arrangement 106 together with a waveguide device;

FIG. 7 shows a schematic side view of a second example of the PCB arrangement 106 together with a waveguide device;

FIG. 8 shows a schematic cut-open side view of a third example of the PCB arrangement 106 together with a waveguide device;

FIG. 9 shows a schematic cut-open side view of a fourth example of a PCB arrangement 106 together with a waveguide device; and

FIG. 10 shows a flowchart for methods according to the present disclosure.

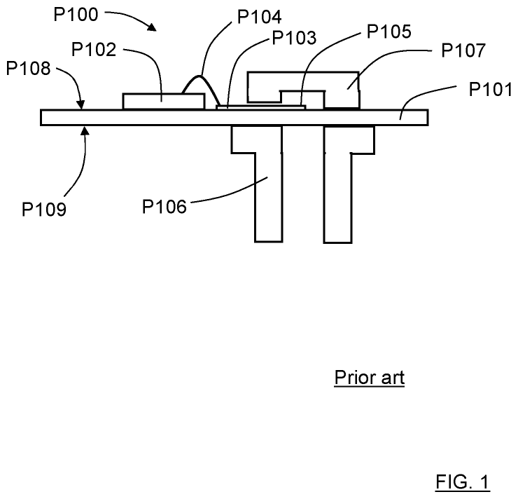

### DETAILED DESCRIPTION

Aspects of the present disclosure will now be described more fully hereinafter with reference to the accompanying drawings. The different devices, systems and methods disclosed herein can, however, be realized in many different forms and should not be construed as being limited to the aspects set forth herein. Like numbers in the drawings refer to like elements throughout.

The terminology used herein is for describing aspects of the disclosure only and is not intended to limit the invention. As used herein, the singular forms “a”, “an” and “the” are intended to include the plural forms as well, unless the context clearly indicates otherwise.

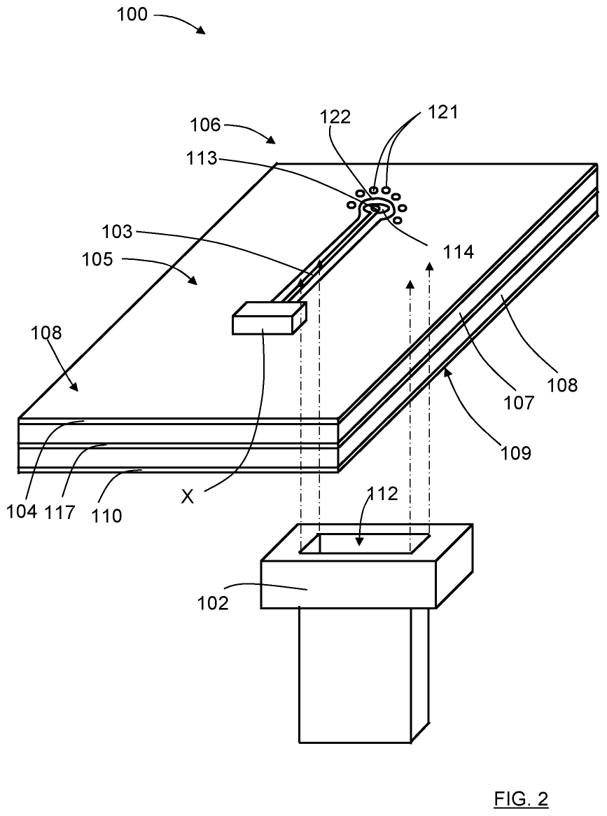

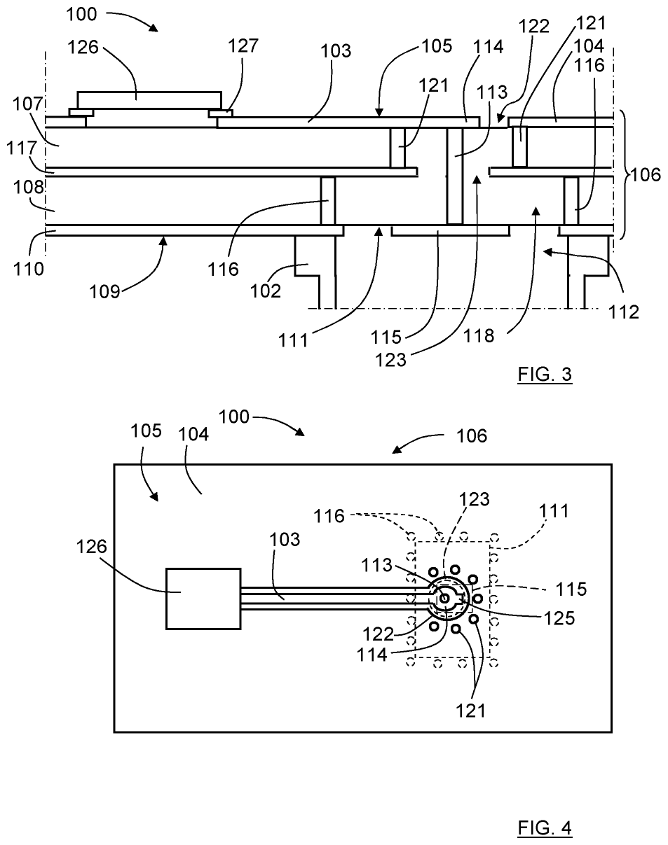

According to a first example, with reference to FIG. 2, showing a schematic perspective exploded view, FIG. 3, showing a schematic cut-open side view, and FIG. 4, showing a schematic top view, there is waveguide interface arrangement 100 that comprises a printed circuit board (PCB) arrangement 106 and a waveguide device 102, where the PCB arrangement 106 arranged for electrically connecting the waveguide device 102 to a microwave conductor 103. The PCB arrangement 106 can be regarded as comprising a waveguide transition arrangement. The present disclosure relates to the PCB arrangement 106 in itself as well as the waveguide interface arrangement 100.

The PCB arrangement 106 comprises at least one PCB dielectric layer 107, 108, and a first PCB main side 105 with a first PCB metallization 104, where the microwave conductor 103 is formed in the first PCB metallization 104. The PCB arrangement 106 further comprises a second PCB main side 109 with a second PCB metallization 110, and an aperture 111 in the second PCB metallization 110. In the first example there is a first dielectric layer 107 and a second dielectric layer 108, and between these layers 107, 108 there is an intermediate PCB metallization 117. The second PCB main side 109 is adapted for attachment of a waveguide device 102 via the aperture 111 that is adapted to correspond to a waveguide aperture 112.

According to the present disclosure, the PCB arrangement 106 further comprises a via connection 113 running between, and electrically connecting, a microwave conductor end portion 114 and a radiating element 115 arranged in the aperture 111, and a first electric connection arrangement 116 running between, and electrically connecting, the second PCB metallization 110 and an adjacent PCB metallization 117 comprised in the PCB arrangement 106. In the first example, the adjacent PCB metallization is the intermediate PCB metallization 117, but other alternatives are possible, some examples are provided later.

The first electric connection arrangement 116 is arranged to circumvent the aperture 111 such that a waveguide backshort 118 is formed in the PCB arrangement 106, the waveguide backshort 118 being limited by the first connection arrangement 116 and the adjacent PCB metallization 117, here the intermediate PCB metallization 117.

This means that a waveguide backshort 118 is obtained within the PCB arrangement 106, no separate part being needed or having to be mounted in order to obtain a waveguide backshort. According to some aspects, front-end circuitry and ICs can be positioned on the first PCB main side 105, and a waveguide device 102 can be positioned on the second PCB main side 109. As illustrated in FIG. 3, the PCB arrangement 106 can for example comprise at least one electronic component 126, such as a front-end IC, mounted to the first PCB main side 105. According to some aspects, the electronic component 126 is connected to the microwave conductor 103 by means of a connector lead 127.

The present disclosure enables integration of an entire planar transmission line to waveguide transition in a PCB, according to some aspects the PCB is a standard multi-layer RF (radio frequency) laminate. Alternatively, the principle of the PCB arrangement 106 according to the present disclosure can also be realized in e.g. substrate technology. The PCB arrangement 106 allows a low-cost packaging of front-end ICs operating beyond 130 GHz as the transition may consist of a standard PCB.

The first PCB main side 105 can thus be used for electronic components and the like, whereas the bulkier waveguide mechanics can placed on the second PCB main side 109.

The use of the via connection 113 to connect the microwave conductor end portion 114 and the radiating element 115 results in a short line length between the microwave conductor end portion 114 and the radiating element 115. The effect of this is that the PCB arrangement 106 can be scaled to very high frequencies. The present disclosure thus offers low manufacturing cost and uncomplicated assembly, combined with maintained RF performance. The PCB arrangement 106 is also extremely compact, and several waveguide backshorts 118 can be placed next to each other on one and the same PCB such that several waveguide transition arrangements can be provided.

According to some aspects, as in particular indicated in FIG. 4, the microwave conductor 103 is a coplanar waveguide conductor that is surrounded by at least a part of the rest of the first PCB metallization 104. This provides a compact and reliable design.

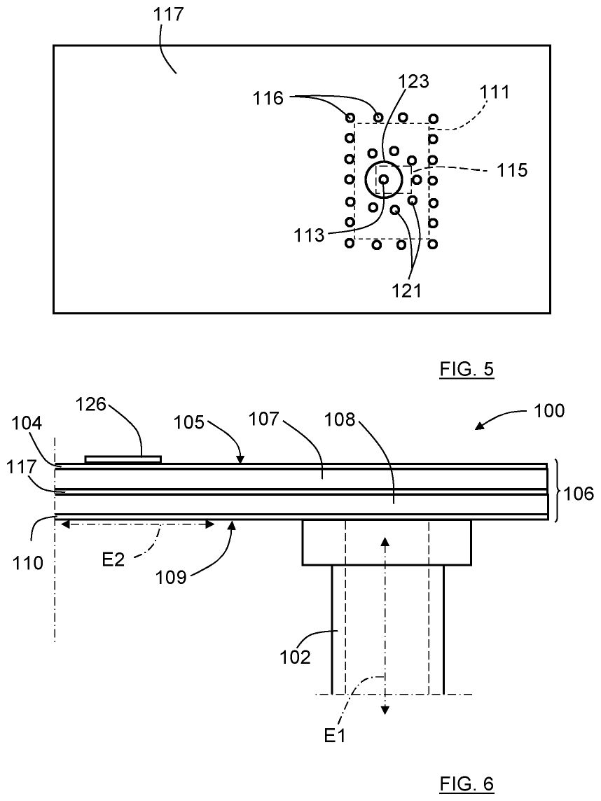

According to some aspects, with reference also to FIG. 5 that corresponds to FIG. 4 with the first dielectric layer 107 removed, the via connection 113 is circumvented by a second electric connection arrangement 121 running between, and electrically connecting, the first PCB metallization 104 and the adjacent PCB metallization 117 that is exposed in FIG. 5. In this example, the adjacent PCB metallization 117 is the intermediate PCB metallization 117. In this way, microwave radiation is prevented from leaking in the first dielectric layer 107, and possible resonances are attenuated.

According to some aspects, at least one electric connection arrangement 116, 121 comprises a plurality of vias. This means that the electric connection arrangement 116, 121 can be accomplished by using well-known technology and manufacturing processes.

Alternatives are possible, for example by inserting metal walls parts in milled or etched slots in the dielectric layers, or by metallizing such slots such that electric connections are established.

According to some aspects, the via connection 113 is running via at least one aperture 122, 123 in a corresponding PCB metallization 104, 117 before reaching the radiating element 115. In this example, there is a first aperture 122 in the first PCB metallization 104 and a second aperture in the intermediate PCB metallization 117.

According to some aspects, as shown in FIG. 4, the microwave conductor end portion 114 comprises a matching portion 125. This can provide desired electrical properties regarding for example transmission and reflection for signal that are being transferred between a mounted waveguide device 102 and the microwave conductor end portion 114.

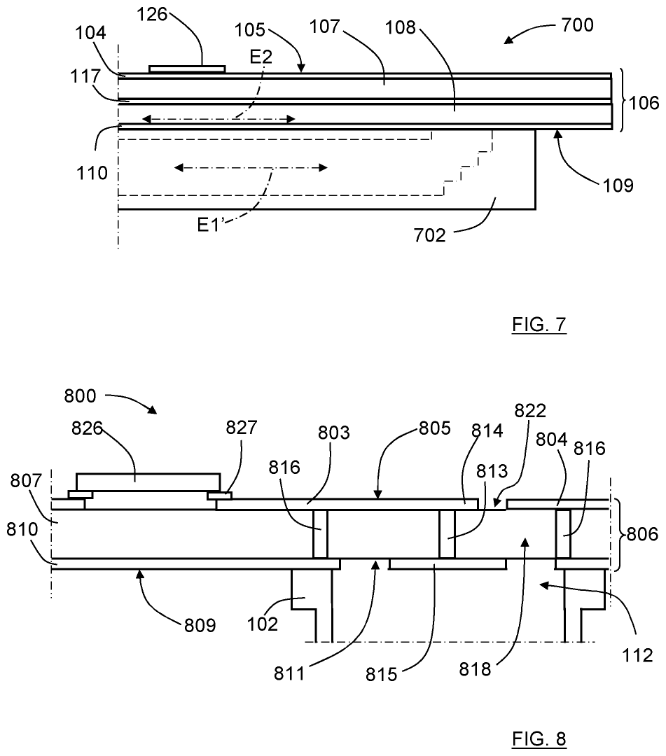

According to some aspects, the PCB arrangement can be adapted for many types of waveguide devices, this is illustrated in FIG. 6 and FIG. 7 where the PCB arrangement is of a similar design as described above. According to some aspects, as shown in FIG. 6 that illustrates the first example, the PCB arrangement 106 is adapted to be mounted to a waveguide device 102 that at least initially has a main extension E1 that runs perpendicular to a main extension E2 of the second PCB main side 109. The PCB arrangement 106 and the mounted waveguide device 102 form a waveguide interface arrangement 100.

According to some aspects, with reference to FIG. 7 that illustrates a second example, the PCB arrangement 706 is adapted to be mounted to a waveguide device 702 that at least initially has a main extension E1′ that runs parallel to a main extension E2 of the second PCB main side 109. The PCB arrangement 706 and the mounted waveguide device 702 form a waveguide interface arrangement 700. This means that the present disclosure is applicable for surface-mounted waveguide designs.

Other configurations of the PCB arrangement are of course conceivable, a few of them will be discussed in the following.

With reference to FIG. 8 that illustrates a third example, there is a PCB arrangement 806 where the adjacent PCB metallization is the first PCB metallization 804. The PCB arrangement 806 comprises a first PCB main side 805 with a first PCB metallization 804, where a microwave conductor 803 is formed in the first PCB metallization 804. The PCB arrangement 806 further comprises a second PCB main side 809 with a second PCB metallization 810, and an aperture 811 in the second PCB metallization 810.

The adjacent PCB metallization is here not an intermediate metallization, the PCB arrangement 806 only comprising one dielectric layer 807 where a waveguide backshort is formed in the dielectric layer 807 by means of an electric connection arrangement 816 running between, and electrically connecting, the second PCB metallization 810 and the adjacent PCB metallization 804 that is the same as the first PCB metallization 804. There is thus no second electric connection arrangement as described above needed, or even possible, here.

A via connection 813 runs in only one dielectric layer and runs between, and electrically connects, a microwave conductor end portion 814 and a radiating element 815 arranged in the aperture 811. The second PCB main side 809 is adapted for attachment of a waveguide device 102 via the aperture 811 that is adapted to correspond to a waveguide aperture 112 such that a waveguide interface arrangement 800 is formed when the waveguide device 102 is mounted.

As in the previous examples, according to some aspects, the electric connection arrangement 816 comprises a plurality of vias. Other alternatives are of course possible.

As in the previous examples, according to some aspects, there can be at least one electronic component 826, such as a front-end IC, mounted to the first PCB main side 805. According to some aspects, the electronic component 826 is connected to the microwave conductor 803 by means of a connector lead 827. All aspects discussed for the previous examples are applicable here as well.

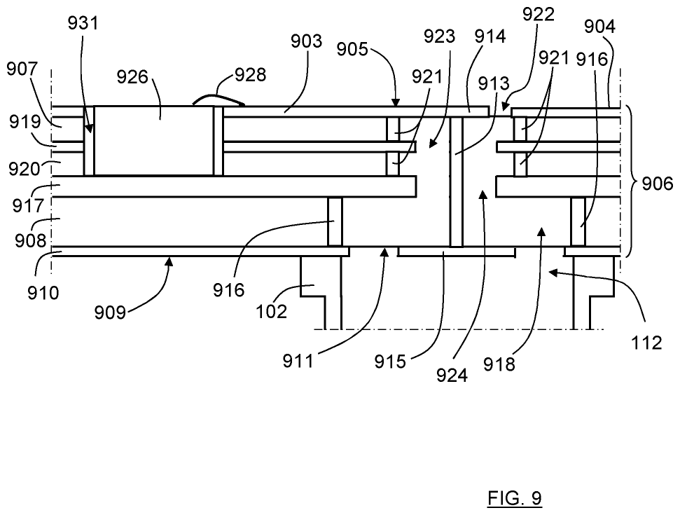

With reference to FIG. 9 that illustrates a fourth example, there is a PCB arrangement 906 where the adjacent PCB metallization 917 is an intermediate PCB metallization, and where there is at least one more intermediate PCB metallization 919. Here, the PCB arrangement 906 comprises a first dielectric layer 907 and a second dielectric layer 920, and between these layers 907, 920 there is a first intermediate PCB metallization 919. There is further is third dielectric layer 908, and between the second dielectric layer 920 and the third dielectric layer 908 there is a second intermediate PCB metallization 917 that is the adjacent PCB metallization 917.

The PCB arrangement 906 further comprises a first PCB main side 905 with a first PCB metallization 904, where the microwave conductor 903 is formed in the first PCB metallization 904. The PCB arrangement 906 further comprises a second PCB main side 909 with a second PCB metallization 910, and an aperture 911 in the second PCB metallization 910.

The second PCB main side 909 is adapted for attachment of a waveguide device 102 via the aperture 911 that is adapted to correspond to a waveguide aperture 112 such that a waveguide interface arrangement 900 is formed when the waveguide device 102 is mounted.

The PCB arrangement 906 further comprises a via connection 913 running between, and electrically connecting, a microwave conductor end portion 914 and a radiating element 915 arranged in the aperture 911, and a first electric connection arrangement 916 running between, and electrically connecting, the second PCB metallization 910 and the adjacent PCB metallization 917. In the same way as described previously, the first electric connection arrangement 916 is arranged to circumvent the aperture 911 such that a waveguide backshort 918 is formed in the PCB arrangement 906, the waveguide backshort 918 being limited by the first connection arrangement 916 and the adjacent PCB metallization 917, here the second intermediate PCB metallization 917.

This means that the waveguide backshort 918 is formed in the third dielectric layer 908, where the via connection 913 is circumvented by a second electric connection arrangement 921 running between, and electrically connecting, the first PCB metallization 904, the first intermediate PCB metallization 919 and the adjacent PCB metallization 917. In this way, microwave radiation is prevented from leaking in the first dielectric layer 907 and the second dielectric layer 920, and possible resonances are attenuated.

As in the previous examples, according to some aspects, the electric connection arrangements 916, 921 comprises a plurality of vias. Other alternatives are of course possible.

As in the previous examples, according to some aspects, there can be at least one electronic component 926, such as a front-end IC, mounted to the first PCB main side 905. Here, an electronic component 926 is placed in an aperture 931 that is formed in the first dielectric layer 907 and the second dielectric layer 920.

According to some aspects, the electronic component 926 is connected to the microwave conductor 903 by means of a bond wire 928. The at least one electronic component 926 can be mounted in this or any other suitable manner, and connections can either be made by bond wires or in any other suitable manner. All aspects discussed for the previous examples are applicable here as well.

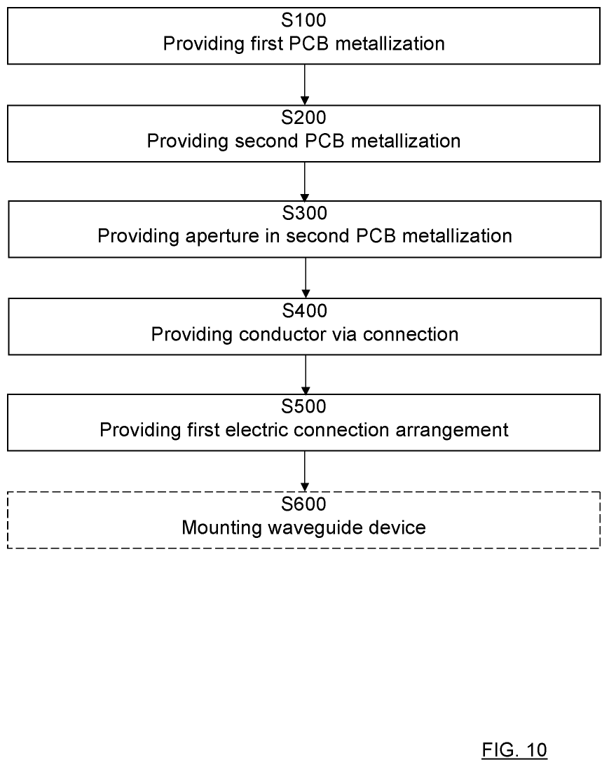

With reference to FIG. 10, the present disclosure also relates to a method for configuring a waveguide interface arrangement 100 used for electrically connecting a waveguide device 102 to a microwave conductor 103 in a printed circuit board arrangement 106. The method comprises providing S100 a first PCB metallization 104 at a first PCB main side 105, providing S200 a second PCB metallization 110 at a second PCB main side 1090 and providing S300 an aperture 111 in the second PCB metallization 110. The second PCB main side 109 is used for attachment of the waveguide device 102 via the aperture 111 that is adapted to correspond to a waveguide aperture 112.

The method further comprises providing S400 a via connection 113 running between, and electrically connecting, a microwave conductor end portion 114 and a radiating element 115 arranged in the aperture 111, and providing S500 a first electric connection arrangement 116 running between, and electrically connecting, the second PCB metallization 110 and an adjacent PCB metallization 117 comprised in the PCB arrangement 106. The first electric connection arrangement 116 is used to circumvent the apertures 111, 112 such that a waveguide backshort 118 is formed in the PCB arrangement 106, the waveguide backshort 118 being limited by the first connection arrangement 116 and the adjacent PCB metallization 117.

According to some aspects, the method comprises mounting S600 the waveguide device 102 to face the aperture 111 in the second PCB metallization 110.

The present disclosure is not limited to the examples provided above, but may vary freely within the scope of the appended claims. For examples, there may be any number of dielectric layers, and any number of intermediate PCB metallizations where there are two or more dielectric layers, Furthermore, there may be two or more dielectric layer without intermediate PCB metallizations.

The dielectric layers and metallization layers may be formed according to any suitable technology with dielectric substrates such as organic, ceramic, or semiconductor materials.

Although the microwave conductor 103 has been described as a coplanar waveguide conductor, the microwave conductor 103 can alternatively be a microstrip conductor, a stripline conductor or a coaxial conductor.

The second electric connection arrangement 116 is shown to have a square configuration that corresponds to a square waveguide. The second electric connection arrangement 116 is of course adapted to fit the waveguide properties of the waveguide device that is intended to be mounted to the PCB arrangement. For example, the second electric connection arrangement 116 can have a circular configuration a circular waveguide.

The second electric connection arrangement 121 has been shown as vias forming a semicircle, see FIG. 4 and FIG. 5. When vias are used, other configurations and placements are possible to obtain the desired result.

As mentioned above, the PCB arrangement 106 comprises a first PCB main side 105 with a first PCB metallization 104, where the microwave conductor 103 is formed in the first PCB metallization 104. It should be noted that the PCB arrangement 106 can be comprised in a larger PCB assembly such that at least one further PCB dielectric layer is positioned on the first PCB main side 105.

1. A printed circuit board, PCB, arrangement arranged for electrically connecting a microwave conductor to a waveguide device, the PCB arrangement comprising:
at least one PCB dielectric layer,
a first PCB main side with a first PCB metallization, where the microwave conductor is formed in the first PCB metallization,
a second PCB main side with a second PCB metallization, and
an aperture in the second PCB metallization, where the second PCB main side is adapted for attachment of a waveguide device via the aperture that is adapted to correspond to a waveguide aperture, wherein the PCB arrangement further comprises
a via connection running between, and electrically connecting, a microwave conductor end portion and a radiating element arranged in the aperture; and
a first electric connection arrangement running between, and electrically connecting, the second PCB metallization and an adjacent PCB metallization comprised in the PCB arrangement,
where the first electric connection arrangement is arranged to circumvent the aperture such that a waveguide backshort is formed in the PCB arrangement, the waveguide backshort being limited by the first connection arrangement and the adjacent PCB metallization.

2. The PCB arrangement according to claim 1, wherein the adjacent PCB metallization is the first PCB metallization.

3. The PCB arrangement according to claim 1, wherein the adjacent PCB metallization is an intermediate PCB metallization.

4. The PCB arrangement according to claim 3, wherein the via connection is circumvented by a second electric connection arrangement running between, and electrically connecting, the first PCB metallization and the adjacent PCB metallization.

5. The PCB arrangement according to claim 1, wherein at least one electric connection arrangement comprises a plurality of vias.

6. The PCB arrangement according to claim 1, wherein the via connection is running via at least one aperture in a corresponding PCB metallization before reaching the radiating element.

7. The PCB arrangement according to claim 1, wherein the microwave conductor end portion comprises a matching portion.

8. The PCB arrangement according to claim 1, wherein the microwave conductor is a coplanar waveguide conductor that is surrounded by at least a part of the rest of the first PCB metallization.

9. The PCB arrangement according to claim 1, wherein the PCB arrangement is adapted to be mounted to a waveguide device that at least initially has a main extension that runs perpendicular to a main extension of the second PCB main side.

10. The PCB arrangement according to claim 1, wherein the PCB arrangement is adapted to be mounted to a waveguide device that at least initially has a main extension that runs parallel to a main extension of the second PCB main side.

11. The PCB arrangement according to claim 1, wherein the PCB arrangement comprises at least one electronic component is mounted to the first PCB main side.

12. The PCB arrangement according to claim 11, wherein the electronic component is connected to the microwave conductor by means of a connector lead or a bond wire.

13. A waveguide interface arrangement comprising the PCB arrangement according to claim 1 and a waveguide device that is mounted to the PCB arrangement.

14. The waveguide interface arrangement according to claim 13, wherein the PCB arrangement is mounted to a waveguide device that at least initially has a main extension that runs perpendicular to a main extension of the second PCB main side.

15. The waveguide interface arrangement according to claim 13, wherein the PCB arrangement is mounted to a waveguide device that at least initially has a main extension that runs parallel to a main extension of the second PCB main side.

16. A method for configuring a waveguide interface arrangement used for electrically connecting a waveguide device to a microwave conductor in a printed circuit board arrangement, where the method comprises:
providing a first PCB metallization at a first PCB main side;
providing a second PCB metallization at a second PCB main side; and
providing an aperture in the second PCB metallization, where the second PCB main side is used for attachment of the waveguide device via the aperture that is adapted to correspond to a waveguide aperture,
wherein the method further comprises
providing a via connection running between, and electrically connecting, a microwave conductor end portion and a radiating element arranged in the aperture; and
providing a first electric connection arrangement running between, and electrically connecting, the second PCB metallization and an adjacent PCB metallization comprised in the PCB arrangement;
where the first electric connection arrangement is used to circumvent the apertures such that a waveguide backshort is formed in the PCB arrangement, the waveguide backshort being limited by the first connection arrangement and the adjacent PCB metallization.

17. The method according to claim 16, wherein the method comprises mounting the waveguide device to face the aperture in the second PCB metallization.
